(19) United States
(12) Patent Application Publication
(10) Pub. No.: US 2022/0020879 A1
(43) Pub. Date: Jan. 20, 2022

(54) SEMICONDUCTOR DEVICE, AND METHOD FOR MANUFACTURING SEMICONDUCTOR DEVICE

(71) Applicant: SONY SEMICONDUCTOR SOLUTIONS CORPORATION, KANAGAWA (JP)

(72) Inventor: KOICHI MATSUMOTO, KANAGAWA (JP)

(21) Appl. No.: 17/297,554

(22) PCT Filed: Nov. 28, 2019
(86) PCT No.: PCT/JP2019/046508

§ 371 Date: May 27, 2021

(30) Foreign Application Priority Data
Dec. 10, 2018 (JP) 2018-230627

(51) Int. Cl. H01L 29/78; H01L 29/66

(52) U.S. Cl. CPC H01L 29/7838; H01L 29/66477

(57) ABSTRACT

Noise in a semiconductor device is to be reduced.

The semiconductor device includes a first semiconductor region, a gate electrode, and a second semiconductor region. In the first semiconductor region, a source region, a channel formation region, and a drain region that are of the same conductivity type are provided. The gate electrode is disposed adjacent to the channel formation region via an insulating film disposed on a surface of the first semiconductor region. The second semiconductor region is disposed adjacent to the channel formation region on a different surface from the surface on which the gate electrode is disposed, and forms a depletion layer in the channel formation region.

### TECHNICAL FIELD

The present disclosure relates to semiconductor devices and methods for manufacturing semiconductor devices. More particularly, the present disclosure relates to a semiconductor device formed in a MOS transistor, and a method for manufacturing the semiconductor device.

### BACKGROUND ART

Conventionally, MOS transistors with improved performance have been used in MOS transistors that are used in imaging devices and the like. For example, a junction FET is used, and this junction FET includes a source impurity region, a channel forming impurity region, and a drain impurity region. In this junction FET, a gate impurity region and a gate electrode are arranged in this order and are disposed adjacent to the surface side of the channel forming impurity region (see Patent Document 1, for example). In this FET, the source impurity region, the channel forming impurity region, and the drain impurity region are designed to be of the n-type, and the channel forming impurity region is designed to be of the p-type. Further, the channel forming impurity region has impurity concentration difference in the channel direction. This concentration difference is larger on the source side and is smaller on the drain side. With this arrangement, transconductance gm can be increased.

### CITATION LIST

### Patent Document

### Patent Document 1: Japanese Patent Application Laid-Open No. 2002-043332

### SUMMARY OF THE INVENTION

### Problems to be Solved by the Invention

In the conventional technology described above, a channel is formed in the vicinity of the surface of the semiconductor substrate on the side without the gate, and noise increases due to the influence of the trap at the interface.

The present disclosure has been made in view of the above problem, and aims to reduce noise in semiconductor devices.

### Solutions to Problems

The present disclosure has been made to solve the above problems, and a first aspect thereof is a semiconductor device that includes: a first semiconductor region in which a source region, a channel formation region, and a drain region that are of the same conductivity type are provided; a gate electrode disposed adjacent to the channel formation region via an insulating film disposed on a surface of the first semiconductor region; and a second semiconductor region that is disposed adjacent to the channel formation region on a different surface from the surface on which the gate electrode is disposed, and forms a depletion layer in the channel formation region.

Also, in this first aspect, the second semiconductor region may be designed to have a different conductivity type from that of the first semiconductor region.

Further, in this first aspect, an electrode disposed adjacent to the second semiconductor region may be further provided.

Also, in this first aspect, the first semiconductor region may be formed on the front surface of the semiconductor substrate, the second semiconductor region may be formed on the back surface of the semiconductor substrate, and the electrode may be disposed adjacent to the back surface of the semiconductor substrate.

Further, in this first aspect, the second semiconductor region may be disposed further adjacent to the source region and the drain region.

Also, in this first aspect, the source region, the channel formation region, and the drain region may be formed in a region protruding from the semiconductor substrate, and the gate electrode may be formed in a shape that surrounds the surface of the channel formation region that protrudes.

Further, in this first aspect, the second semiconductor region may have different thicknesses in the vicinity of the source region and in the vicinity of the drain region.

Also, in this first aspect, the first semiconductor region may be formed on the front surface of the semiconductor substrate, and the second semiconductor region may be formed with a pinning layer that pins the trap level on the back surface of the semiconductor substrate.

Further, in this first aspect, the second semiconductor region may have different impurity concentrations in the vicinity of the source region and in the vicinity of the drain region.

Also, a second aspect of the present disclosure is a semiconductor device that includes: a first semiconductor substrate in which a semiconductor device is disposed, the semiconductor device in the first semiconductor substrate including: a first semiconductor region in which a source region, a channel formation region, and a drain region that are of the same conductivity type are provided; a gate electrode disposed adjacent to the channel formation region via an insulating film disposed on a surface of the first semiconductor region; and a second semiconductor region that is disposed adjacent to the channel formation region on a different surface from the surface on which the gate electrode is disposed, and forms a depletion layer in the channel formation region; and a second semiconductor substrate on which the first semiconductor substrate is stacked.

Further, a third aspect of the present disclosure is a method for manufacturing a semiconductor device. The method includes: a step of forming a first semiconductor region in which a source region, a channel formation region, and a drain region that are of the same conductivity type are provided; a step of forming a gate electrode disposed adjacent to the channel formation region via an insulating film formed on a surface of the first semiconductor region; and a step of forming a second semiconductor region that is disposed adjacent to the channel formation region on a different surface from the surface on which the gate electrode is disposed, and forms a depletion layer in the channel formation region.

As such modes are adopted, a depletion layer is formed on a different surface from the surface of the first semiconductor region on which the gate electrode is disposed. The channel is to be separated from the back surface of the semiconductor substrate.

### BRIEF DESCRIPTION OF DRAWINGS

FIG. 1 is a plan view showing an example configuration of a semiconductor device according to a first embodiment of the present disclosure.

FIG. 2 is a cross-sectional view showing an example configuration of a semiconductor device according to the first embodiment of the present disclosure.

FIG. 3 is diagrams illustrating an example method for manufacturing a semiconductor device according to the first embodiment of the present disclosure.

FIG. 4 is diagrams illustrating an example method for manufacturing a semiconductor device according to the first embodiment of the present disclosure.

FIG. 5 is a diagram illustrating an example method for manufacturing a semiconductor device according to the first embodiment of the present disclosure.

FIG. 6 is a cross-sectional view showing an example configuration of a semiconductor device according to a second embodiment of the present disclosure.

FIG. 7 is a cross-sectional view showing an example configuration of a semiconductor device according to a third embodiment of the present disclosure.

FIG. 8 is a cross-sectional view showing another example configuration of a semiconductor device according to the third embodiment of the present disclosure.

FIG. 9 is diagrams illustrating an example method for manufacturing a semiconductor device according to a fourth embodiment of the present disclosure.

FIG. 10 is a diagram illustrating another example method for manufacturing a semiconductor device according to the fourth embodiment of the present disclosure.

FIG. 11 is a diagram illustrating another example method for manufacturing a semiconductor device according to the fourth embodiment of the present disclosure.

FIG. 12 is diagrams illustrating another example method for manufacturing a semiconductor device according to the fourth embodiment of the present disclosure.

FIG. 13 is a cross-sectional view showing an example configuration of a semiconductor device according to a fifth embodiment of the present disclosure.

FIG. 14 is a cross-sectional view showing an example configuration of a semiconductor device according to a sixth embodiment of the present disclosure.

FIG. 15 is a plan view showing an example configuration of a semiconductor device according to a seventh embodiment of the present disclosure.

FIG. 16 is diagrams showing an example configuration of a semiconductor device according to the seventh embodiment of the present disclosure.

FIG. 17 is a diagram showing an example configuration of an imaging device to which the present technology can be applied.

FIG. 18 is a diagram showing an example configuration of a pixel to which the present technology can be applied.

FIG. 19 is a cross-sectional view showing an example configuration of an imaging device to which the present technology can be applied.

### MODES FOR CARRYING OUT THE INVENTION

Next, modes for carrying out the present disclosure (the modes will be hereinafter referred to as embodiments) are described with reference to the drawings. In the drawings mentioned below, the same or similar components are denoted by the same or similar reference numerals. Further, explanation of the embodiments will be made in the following order.

1. First Embodiment

2. Second Embodiment

3. Third Embodiment

4. Fourth Embodiment

5. Fifth Embodiment

6. Sixth Embodiment

7. Seventh Embodiment

8. Example application to an imaging device

### 1. First Embodiment

[Configuration of a Semiconductor Device]

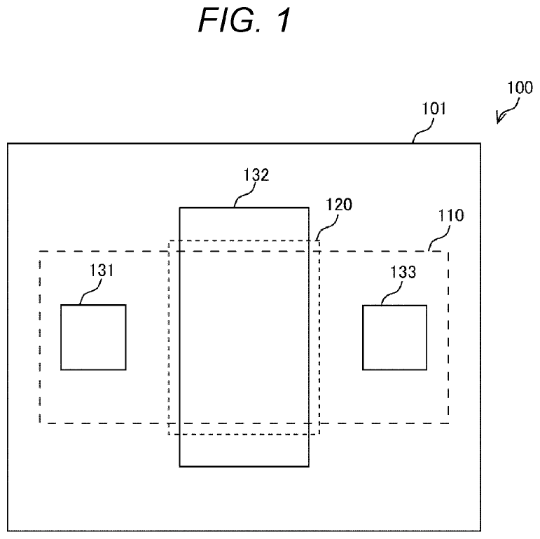

FIG. 1 is a plan view showing an example configuration of a semiconductor device according to a first embodiment of the present disclosure. This drawing is a diagram showing an example configuration of a semiconductor device 100. The semiconductor device 100 in the drawing is formed on a semiconductor substrate 101. A first semiconductor region 110 and a second semiconductor region 120 are formed in the semiconductor substrate 101. Further, a source electrode 131, a gate electrode 132, and a drain electrode 133 are disposed on a surface of the semiconductor substrate 101. As will be described later, the gate electrode 132 is disposed adjacent to the first semiconductor region 110 via an insulating film 140. The semiconductor device 100 in the drawing is formed with a metal oxide semiconductor (MOS) transistor.

[Configuration of a Cross-Section of a Semiconductor Device]

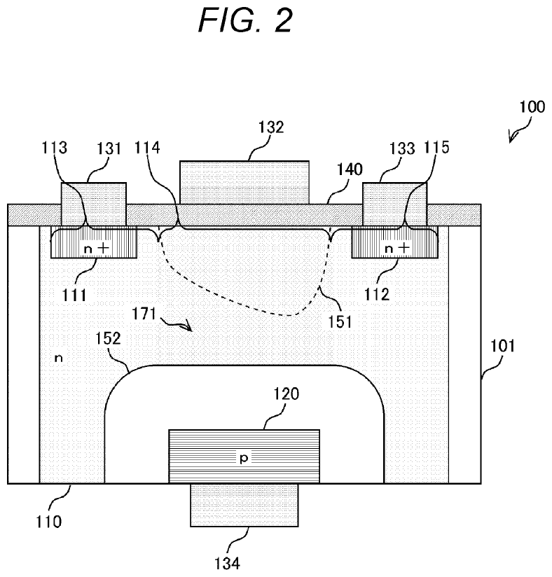

FIG. 2 is a cross-sectional view showing an example configuration of a semiconductor device according to the first embodiment of the present disclosure. The semiconductor device 100 in the drawing includes the semiconductor substrate 101, the first semiconductor region 110, the second semiconductor region 120, high-concentration impurity regions 111 and 112, the insulating film 140, the source electrode 131, the drain electrode 133, and a back-surface electrode 134. Further, the semiconductor device 100 in the drawing also includes the gate electrode 132.

The semiconductor substrate 101 is the semiconductor substrate on which the semiconductor device 100 is formed. This semiconductor substrate 101 may include silicon (Si), for example. Note that the semiconductor substrate 101 is an example of the first semiconductor substrate disclosed in the claims.

The first semiconductor region 110 is the region in which a source region 113, a channel formation region 114, and a drain region 115 of the semiconductor device 100 are formed. This first semiconductor region 110 is a region designed to have a predetermined impurity concentration, and the majority carriers of the semiconductor device 100 exist therein. Further, the first semiconductor region 110 is designed to be of one conductivity type. The first semiconductor region 110 in the drawing shows an example designed to have n-type conductivity.

The source region 113 and the drain region 115 are regions formed in the first semiconductor region 110, and are the regions that form the source and the drain of the semiconductor device 100, respectively. The source region 113 and the drain region 115 are regions to and from which majority carriers are supplied and discharged, respectively. As the majority carriers move in the first semiconductor region 110, electric current flows between the source region 113 and the drain region 115.

The channel formation region 114 is a region that is formed in the first semiconductor region 110 and is located between the source region 113 and the drain region 115. A channel 171 that is the passage for the majority carriers is formed in this channel formation region 114. Further, the gate electrode 132 is disposed in the vicinity of and adjacent to the channel formation region 114 via the insulating film 140.

The high-concentration impurity regions 111 and 112 are semiconductor regions formed near the surface of the first semiconductor region 110. The high-concentration impurity regions 111 and 112 are disposed in the source region 113 and the drain region 115, respectively, and are designed to have a higher impurity concentration than that of the first semiconductor region 110 and be of the same conductivity type. As a result, the high-concentration impurity regions 111 and 112 form an ohmic junction between the source electrode 131 and the drain electrode 133, which will be described later.

The source electrode 131 and the drain electrode 133 are electrodes that are disposed adjacent to the high-concentration impurity regions 111 and 122, respectively, and correspond to the source region 113 and the drain region 115. The source electrode 131 and the drain electrode 133 can include aluminum (Al), for example.

The insulating film 140 is a film of an insulator formed on the surface of the semiconductor substrate 101. This insulating film 140 can include an oxide such as silicon oxide (SiO₂) or a nitride such as silicon nitride (SiN), for example. Note that the insulating film 140 formed directly under the gate electrode 132 forms a gate oxide film.

The gate electrode 132 is an electrode disposed adjacent to the channel formation region 114 via the insulating film 140. As a voltage is applied to this gate electrode, the current flowing between the source region 113 and the drain region 115 can be controlled. Specifically, a voltage that is negative with respect to the source region 113 and the drain region 115 is applied to the gate electrode 132, so that a depletion layer is formed in the channel formation region 114. This depletion layer narrows the width of the channel 171, and allows control on the current flowing between the source region 113 and the drain region 115.

In a case where no gate voltage is to be applied, the depletion layer 151 is not formed, and the current flowing between the source region 113 and the drain region 115 is maximized. An increase in the voltage to be applied to the gate electrode 132 expands the depletion layer, and reduces the current flowing between the source region 113 and the drain region 115. The dashed line in the drawing indicates an example of the depletion layer 151 formed in the channel formation region 114. The depletion layer 151 in the drawing shows an example case where a relatively high voltage is applied to the gate electrode. As shown in the drawing, the depletion layer 151 is larger in the vicinity of the drain region 115 than in the vicinity of the source region 113. This is because the resistance existing in the channel formation region 114 causes the potential generated by the current flowing in the channel formation region 114 to be higher in the vicinity of the drain region 115 than in the vicinity of the source region 113. It is possible to form the depletion layer by applying an input signal to the gate electrode 132, and causes a current corresponding to the input voltage to flow between the source region 113 and the drain region 115.

The second semiconductor region 120 is a semiconductor region formed on a different surface from the surface of the first semiconductor region 110 on which the gate electrode 132 is disposed. The second semiconductor region 120 is a region that is formed adjacent to the channel formation region 114, and forms a depletion layer in the channel formation region 114. The second semiconductor region 120 in the drawing is designed to be of the p-type, which is a different conductivity type from that of the first semiconductor region 110. With this arrangement, a p-n junction is formed between the second semiconductor region 120 and the first semiconductor region 110, and a depletion layer 152 is formed.

The back-surface electrode 134 is an electrode that is disposed adjacent to the second semiconductor region 120, and applies a voltage to the second semiconductor region 120. It is possible to adjust the size of the depletion layer 152 by changing the voltage to be applied to the back-surface electrode 134. Note that, unlike the gate electrode 132, the back-surface electrode 134 has a voltage of a predetermined value to be applied thereto.

As the second semiconductor region 120 is formed, the depletion layer 152 can be formed on the back surface of the first semiconductor region 110. With this arrangement, the channel 171 can be separated from the back surface of the semiconductor substrate 101 (or the end face of the first semiconductor region 110). A trap is formed at the interface on the back surface of the semiconductor substrate 101, and, when the channel 171 is close to the trap, the majority carriers are affected by the trap. Specifically, when the majority carriers are captured or recombined at the trap, current fluctuations are caused, and noise is generated. In a case where the semiconductor substrate 101 is thinned as in the semiconductor device 100 to be used in the imaging device 1 described later, the influence of the trap at the interface on the back surface of the semiconductor substrate 101 becomes conspicuous. Therefore, the second semiconductor region 120 is disposed to form the depletion layer 152, and the channel 171 is separated from the end face of the semiconductor substrate 101. The influence of the trap on the majority carriers can be reduced.

[Method for Manufacturing a Semiconductor Device]

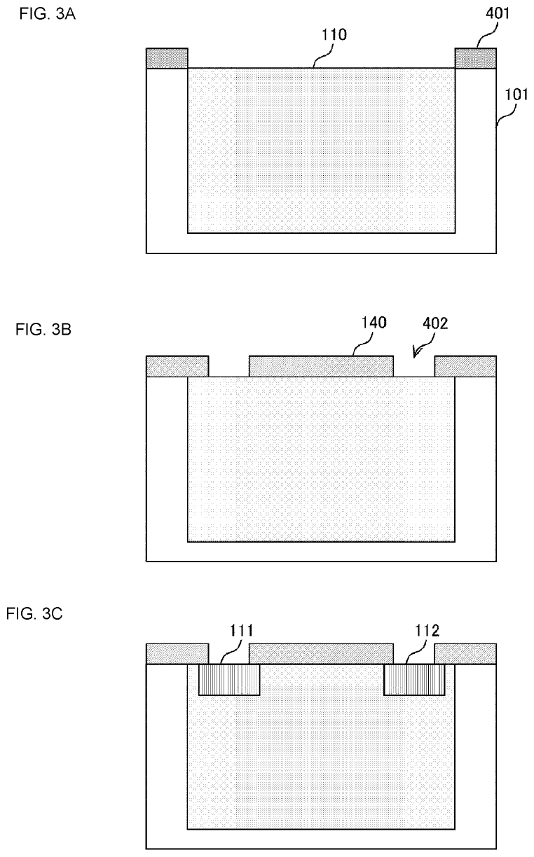

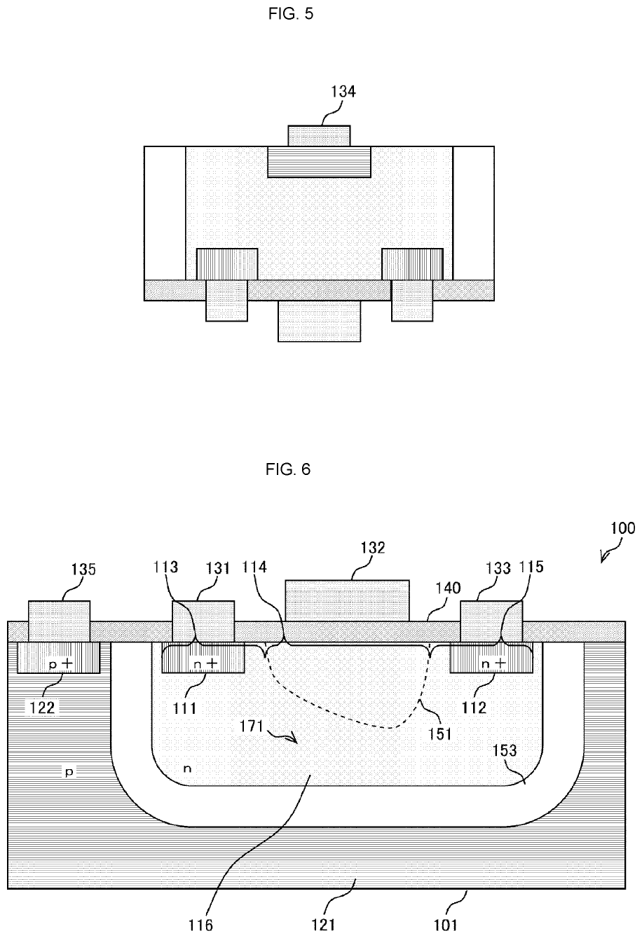

FIGS. 3 to 5 are diagrams illustrating an example method for manufacturing a semiconductor device according to the first embodiment of the present disclosure. FIGS. 3 to 5 are diagrams showing an example of steps for manufacturing the semiconductor device 100. First, the first semiconductor region 110 is formed in the semiconductor substrate 101. This can be done by forming a resist 401 on a surface of the semiconductor substrate 101, and introducing impurities such as phosphorus (P), with the resist 401 serving as a mask. Note that impurities can be introduced by ion implantation or thermal diffusion (A of FIG. 3). This step is an example of the step of forming a first semiconductor region disclosed in the claims.

Next, the insulating film 140 is formed on the surface of the semiconductor substrate 101, and openings 402 are formed in the regions in which the source electrode 131 and the drain electrode 133 are to be formed (B of FIG. 3). Next, impurities such as P are introduced by thermal diffusion, with the insulating film 140 serving as a mask. As a result, the high-concentration impurity regions 111 and 122 can be formed (C of FIG. 3). Note that, in the drawing, the insulating film used for forming the high-concentration impurity regions 111 and 122 is used as the insulating film 140, for convenience sake. However, the insulating film may be removed, and an insulating film 140 having its thickness and the like adjusted can be newly formed.

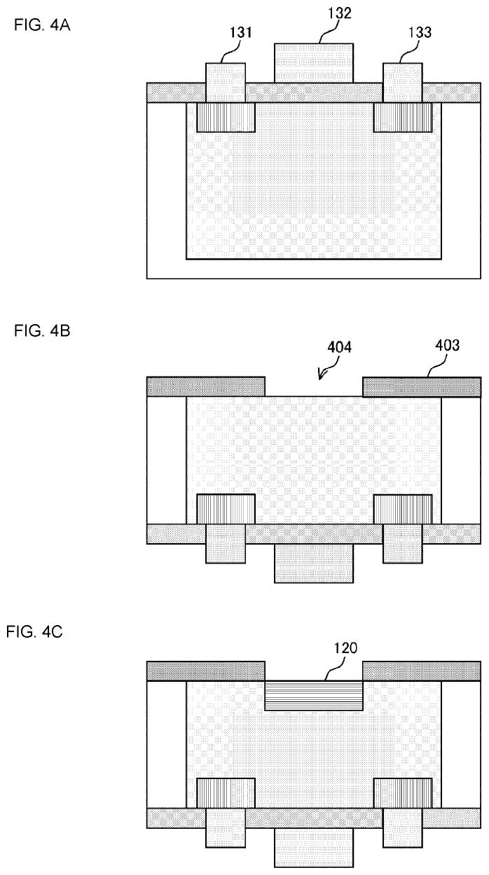

Next, a metal film such as an Al film is formed on the surface of the semiconductor substrate 101, and etching is performed, to form the source electrode 131, the drain electrode 133, and the gate electrode 132 (D of FIG. 4). This step is an example of the step of forming a gate electrode disclosed in the claims.

Next, the back surface of the semiconductor substrate 101 is ground and thinned. The top and bottom of this thinned semiconductor substrate are reversed, and a resist 403 is disposed on the back surface. In this resist 403, an opening 404 is formed in the region in which the second semiconductor region 120 is to be formed (E of FIG. 4). With this resist 403 serving as a mask, impurities such as boron (B) are introduced, to form the second semiconductor region 120 (F of FIG. 4). This step is an example of the step of forming a second semiconductor region disclosed in the claims.

Next, the resist 403 is removed, and the back-surface electrode 134 is formed. This can be done by forming a metal film on the back surface of the semiconductor substrate 101 and subjecting the metal film to etching. Through the above steps, the semiconductor device 100 can be manufactured.

As described above, in the semiconductor device 100 of the first embodiment of the present disclosure, the second semiconductor region 120 is formed on the back surface of the semiconductor substrate 101, which is the end of the first semiconductor region 110. With this arrangement, the channel 171 is separated from the interface on the back surface of the semiconductor substrate 101. Thus, the influence of the trap at the interface on the back surface of the semiconductor substrate 101 can be reduced, and noise can also be reduced.

### 2. Second Embodiment

In the semiconductor device 100 of the first embodiment described above, the second semiconductor region 120 is formed on the back surface of the semiconductor substrate 101. On the other hand, a semiconductor device 100 of a second embodiment of the present disclosure differs from the first embodiment described above in that a well region of the semiconductor substrate 101 is used as the second semiconductor region.

[Configuration of a Cross-Section of a Semiconductor Device]

FIG. 6 is a cross-sectional view showing an example configuration of a semiconductor device according to the second embodiment of the present disclosure. The semiconductor device 100 in the drawing differs from the semiconductor device 100 described with reference to FIG. 1, in including a first semiconductor region 116 and a second semiconductor region 121 in place of the first semiconductor region 110 and the second semiconductor region 120, and including an electrode 135 in place of the back-surface electrode 134.

The second semiconductor region 121 in the drawing corresponds to the well region formed in the semiconductor substrate 101. The first semiconductor region 116 is formed in the second semiconductor region 121. A depletion layer 153 is formed between the first semiconductor region 116 and the second semiconductor region 121. This depletion layer 153 separates the channel 171 from the end face of the back surface of the semiconductor substrate 101. As the well region is used as the second semiconductor region 121 in this manner, the step of manufacturing the second semiconductor region 121 can be simplified. Further, as shown in the drawing, the second semiconductor region 121 is formed adjacent to the source region 113 and the drain region 115 as well as the channel formation region 114. Thus, the source region 113 and the drain region 115 can be separated from the other adjacent semiconductor devices.

The electrode 135 in the drawing is an electrode that forms a so-called well contact, and is to be connected to the second semiconductor region 121. Note that a high-concentration impurity region 122 is disposed between the first semiconductor region 121 and the electrode 135.

The other components of the semiconductor device 100 are similar to the components of the semiconductor device 100 described in the first embodiment of the present disclosure, and therefore, explanation of them is not made herein.

As described above, in the semiconductor device 100 of the second embodiment of the present disclosure, the well region formed in the semiconductor substrate 101 is used as the second semiconductor region, so that the channel 171 is separated from the interface on the back surface of the semiconductor substrate 101. Thus, the step of manufacturing the second semiconductor region 121 can be simplified, and the semiconductor device 100 can be separated from the other adjacent semiconductor devices.

### 3. Third Embodiment

In the semiconductor device 100 of the first embodiment described above, the distance from the back surface of the semiconductor substrate 101 to the edge of the depletion layer is uniform in the vicinities of the source region 113 and the drain region 115. On the other hand, a semiconductor device 100 of a third embodiment of the present disclosure differs from the first embodiment described above in that the distance from the back surface of the semiconductor substrate 101 to the edge of the depletion layer is designed to vary in the vicinities of the source region 113 and the drain region 115.

[Configuration of a Cross-Section of a Semiconductor Device]

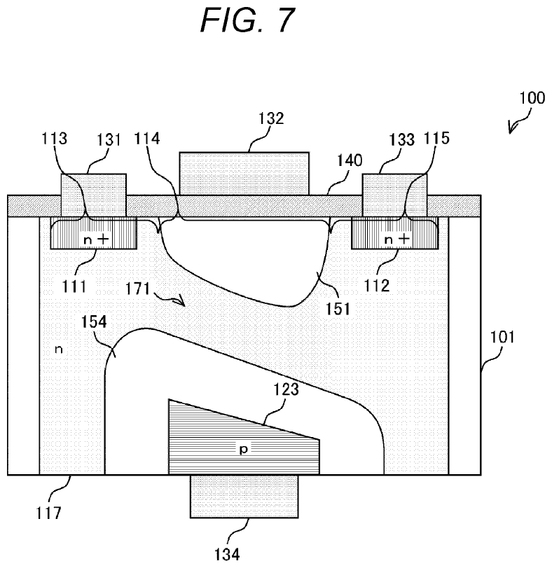

FIG. 7 is a cross-sectional view showing an example configuration of a semiconductor device according to the third embodiment of the present disclosure. The semiconductor device 100 in the drawing differs from the semiconductor device 100 described with reference to FIG. 1, in including a first semiconductor region 117 and a second semiconductor region 123 in place of the first semiconductor region 110 and the second semiconductor region 120.

The second semiconductor region 123 is formed adjacent to the first semiconductor region 117 in the semiconductor device 100 in the drawing. This second semiconductor region 123 is formed so that the distance (depth) from the back surface of the semiconductor substrate 101 varies between the source region 113 and the drain region 115. Specifically, the thickness (depth) of the second semiconductor region 123 is designed to be smaller in the vicinity of the drain region 115 than in the vicinity of the source region 113. Therefore, a depletion layer 154 between the first semiconductor region 117 and the second semiconductor region 123 is designed to have a different shape from that of the depletion layer 152 shown in FIG. 2. Specifically, the distance from the back surface of the semiconductor substrate 101 to the edge of the depletion layer 154 is shorter in the vicinity of the drain region 115 than in the vicinity of the source region 113.

This drawing shows an example case where a relatively high voltage is applied to the gate electrode 132 as in FIG. 2, and shows a state in which the depletion layer 151 is formed in the channel formation region 114. As described above with reference to FIG. 2, the depletion layer 151 is thicker in the vicinity of the drain region 115 than in the vicinity of the source region 113. Therefore, the channel 171 is narrower in the vicinity of the drain region 115, and the operation margin between the gate and the drain is small. In the source region 113, on the other hand, the depletion layer 151 is thinner. Therefore, the amount of change in the current at the channel 171 when the voltage on the source side changes is larger, and the influence of the change in the source voltage on the drain current is greater.

However, it is possible to make the width of the channel 171 almost uniform in the vicinities of the source region 113 and the drain region 115 by changing the shape of the edge of the depletion layer 154 as shown in the drawing. With this arrangement, the influence of the voltages to be applied to the source and the drain can be made uniform. Further, it is possible to adjust the influence of the voltages to be applied to the source and the drain by adjusting the shape of the edge of the depletion layer 154.

[Another Configuration of a Cross-Section of a Semiconductor Device]

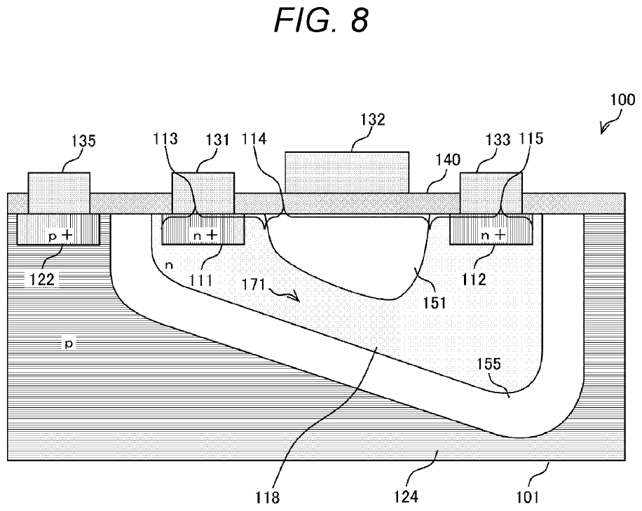

FIG. 8 is a cross-sectional view showing another example configuration of a semiconductor device according to the third embodiment of the present disclosure. This drawing is a diagram showing an example in which a second semiconductor region 124 is provided in place of the second semiconductor region 121 in the semiconductor device 100 described above with reference to FIG. 6. In this drawing, the second semiconductor region 124 is disposed adjacent to a first semiconductor region 118. The thickness of this second semiconductor region 124 is designed to be smaller in the vicinity of the drain region 115 than in the vicinity of the source region 113. With this arrangement, the width of the channel 171 can be made almost the same in the vicinities of the source region 113 and the drain region 115.

The other components of the semiconductor device 100 are similar to the components of the semiconductor device 100 described in the first embodiment of the present disclosure, and therefore, explanation of them is not made herein.

As described above, in the semiconductor device 100 of the third embodiment of the present disclosure, the distance from the back surface of the semiconductor substrate 101 to the edges of the depletion layers 154 and 155 is adjusted in the vicinity of the source region 113 and in the vicinity of the drain region 115. Thus, the semiconductor device 100 with desired characteristics can be formed.

### 4. Fourth Embodiment

In a semiconductor device 100 of the third embodiment described above, the distance from the back surface of the semiconductor substrate 101 to the edge of the depletion layer varies in the vicinities of the source region 113 and the drain region 115. A method for manufacturing this semiconductor device 100 is suggested in a fourth embodiment.

[Method for Manufacturing a Semiconductor Device]

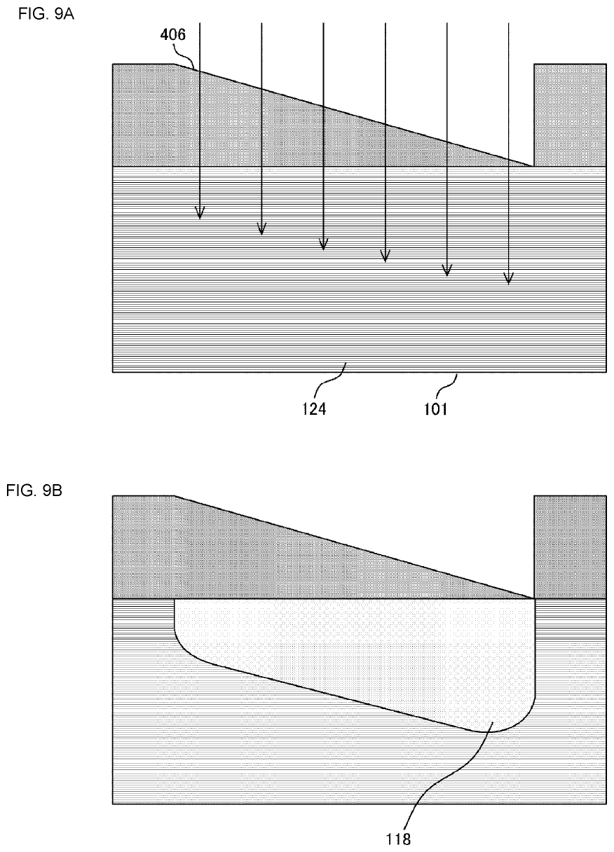

FIG. 9 is diagrams illustrating an example method for manufacturing a semiconductor device according to the fourth embodiment of the present disclosure. These drawings are diagrams showing the step of forming the first semiconductor region 118 in the second semiconductor region 124 in the semiconductor device 100 described above with reference to FIG. 8.

First, the second semiconductor region 124, which is a well region, is formed in the semiconductor substrate 101. This can be done by ion implantation, for example. Alternatively, an epitaxial wafer having a predetermined impurity concentration can be used, for example. A resist 406 is formed on a surface of the second semiconductor region 124. This resist 406 is designed to have a thickness depending on the shape of the first semiconductor region 118. Specifically, the resist 406 is designed to have a shape in which a slope is formed on the surface of the region forming the first semiconductor region 118. This resist 406 can be formed by controlling the thickness of a resist using a gradation mask, for example. Next, impurity ion implantation is performed (A of FIG. 9). Note that arrows in the drawing indicate this ion implantation.

At this stage, the depth of introduction of impurity ions into the semiconductor substrate 101 varies with the thickness of the resist 406. Therefore, the first semiconductor region 118 having varying depth can be formed (B in the drawing). Thus, the second semiconductor region 124 having a shape that varies in the vicinities of the source region 113 and the drain region 115 can be formed.

[Other Methods for Manufacturing a Semiconductor Device]

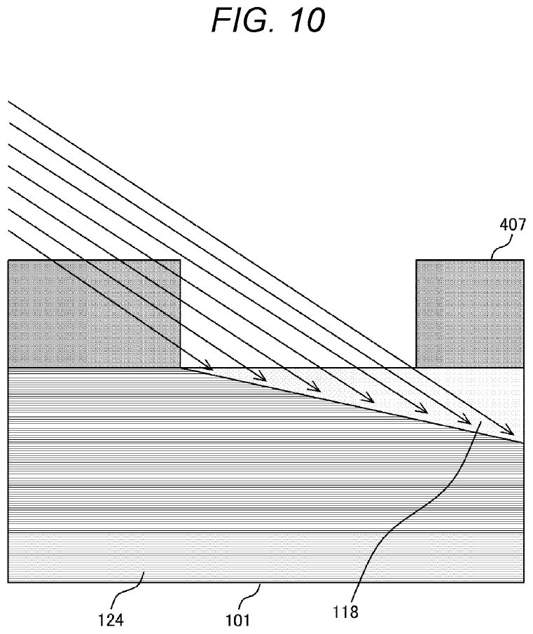

FIG. 10 is a diagram illustrating another example method for manufacturing a semiconductor device according to the fourth embodiment of the present disclosure. In this drawing, a resist 407 having an opening in the region forming the first semiconductor region 118 is disposed on the surface of the semiconductor substrate 101, and impurity ion implantation is performed from an oblique direction. Thus, the second semiconductor region 124 having a shape that varies in the vicinities of the source region 113 and the drain region 115 is formed.

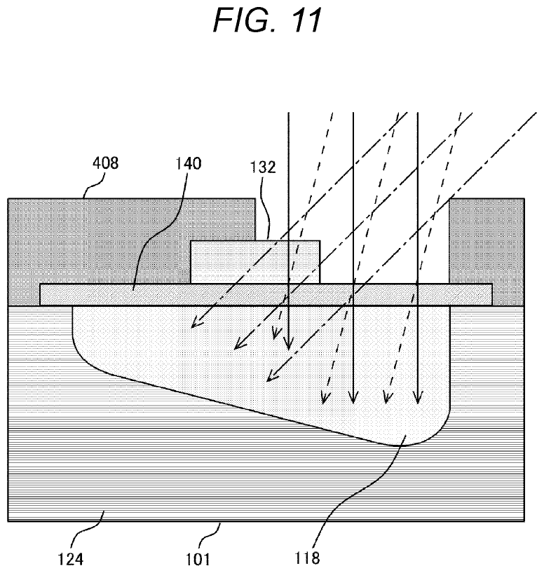

FIG. 11 is a diagram illustrating another example method for manufacturing a semiconductor device according to the fourth embodiment of the present disclosure. In this drawing, the insulating film 140 and the gate electrode 132 are formed on the surface of the second semiconductor region 124, and a resist 408 is provided thereon. An opening extending from the central portion of the gate electrode 132 to the vicinity of the drain region 115 is formed in the resist 408. Next, impurity ion implantation is performed. This ion implantation is performed a plurality of times at different angles. Solid arrows in the drawing indicate ion implantation in a direction perpendicular to the surface of the semiconductor substrate 101. Dashed lines in the drawing indicate ion implantation at an angle of 30 degrees with respect to the vertical direction. Dot-and-dash lines in the drawing indicate ion implantation at an angle of 45 degrees with respect to the vertical direction. As ion implantation at various angles is performed in this manner, so that the gate electrode 132 can be used as a mask, and the second semiconductor region 124 having a shape that varies in the vicinities of the source region 113 and the drain region 115 can be formed.

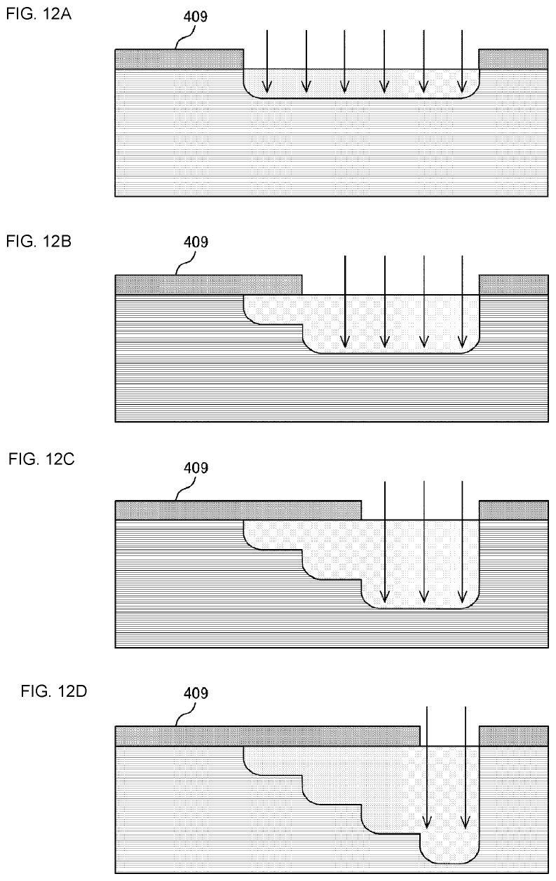

FIG. 12 is diagrams illustrating another example method for manufacturing a semiconductor device according to the fourth embodiment of the present disclosure. In this drawing, ion implantation is performed a plurality of times on the semiconductor substrate 101 on which a mask 409 is provided (A to D in the drawing). At this stage, the opening in the mask 409 is made gradually smaller, and the energy for ion implantation is increased. Thus, the second semiconductor region 124 having a shape that varies in the vicinities of the source region 113 and the drain region 115 can be formed.

### 5. Fifth Embodiment

The semiconductor device 100 of the first embodiment described above uses the second semiconductor region 120 of a different conductivity type from that of the first semiconductor region 110. On the other hand, a semiconductor device 100 of a fifth embodiment of the present disclosure differs from the first embodiment described above in using a pinning region formed on the back surface of the first semiconductor region 110 as the second semiconductor region.

[Configuration of a Cross-Section of a Semiconductor Device]

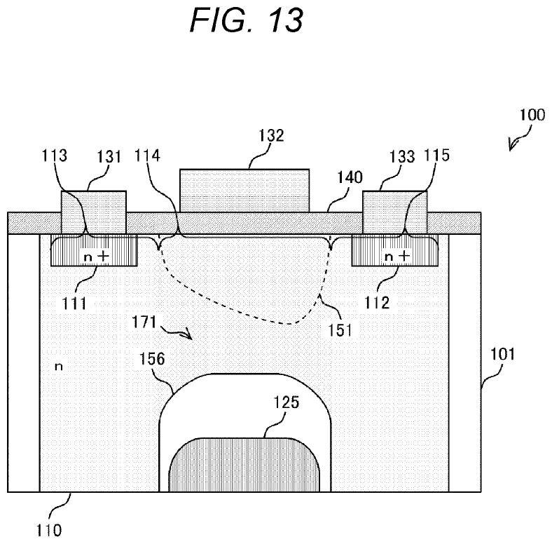

FIG. 13 is a cross-sectional view showing an example configuration of a semiconductor device according to the fifth embodiment of the present disclosure. The semiconductor device 100 in this drawing differs from the semiconductor device 100 described above with reference to FIG. 2 in including a second semiconductor region 125 in place of the second semiconductor region 120.

The second semiconductor region 125 in this drawing is a pinning region formed on the back surface of the semiconductor substrate. Here, the pinning region is a region in which an impurity that terminates the trap level at the interface with the semiconductor substrate, such as hafnium (Hf), is introduced, for example. As a result of terminating the trap level with the introduced Hf, a positively charged region is formed, and a depletion layer 156 is formed between the pinning region and the first semiconductor region 110. Note that the introduction of Hf can be performed by ion implantation.

The other components of the semiconductor device 100 are similar to the components of the semiconductor device 100 described in the first embodiment of the present disclosure, and therefore, explanation of them is not made herein.

As described above, the semiconductor device 100 of the fifth embodiment of the present disclosure can separate the channel 171 from the interface on the back surface of the semiconductor substrate 101, using the second semiconductor region 125 formed with a pinning region.

### 6. Sixth Embodiment

In the semiconductor device 100 of the fifth embodiment described above, a pinning region formed on the back surface of the first semiconductor region 110 is used as the second semiconductor region 126. On the other hand, a semiconductor device 100 of a sixth embodiment of the present disclosure differs from the fifth embodiment described above in that the distance from the back surface of the semiconductor substrate 101 to the depletion layer is designed to vary in the vicinities of the source region 113 and the drain region 115.

[Configuration of a Cross-Section of a Semiconductor Device]

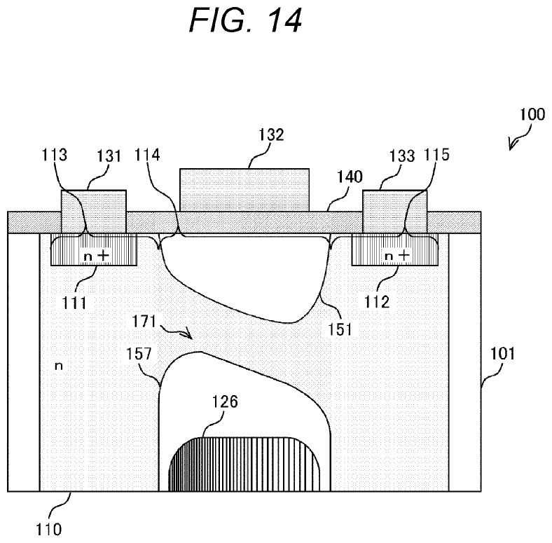

FIG. 14 is a cross-sectional view showing an example configuration of a semiconductor device according to the sixth embodiment of the present disclosure. The semiconductor device 100 in this drawing differs from the semiconductor device 100 described above with reference to FIG. 13 in including a second semiconductor region 126 in place of the second semiconductor region 125.

The second semiconductor region 126 in the drawing differs from the semiconductor device 100 described above with reference to FIG. 13 in that Hf at varying concentration is introduced in the vicinities of the source region 113 and the drain region 115. Specifically, Hf is introduced at a lower concentration in the vicinity of the drain region 115 than in the vicinity of the source region 113. In the drawing, the differences in concentration are indicated by shades in the second semiconductor region 126. With this arrangement, the thickness of a depletion layer 157 in the vicinity of the source region 113 can be made greater.

The other components of the semiconductor device 100 are similar to the components of the semiconductor device 100 described in the first embodiment of the present disclosure, and therefore, explanation of them is not made herein.

As described above, the semiconductor device 100 of the fifth embodiment of the present disclosure can adjust the distance from the back surface of the semiconductor substrate 101 to the edge of the depletion layer 157, using the second semiconductor region 126 formed with a pinning region in which impurity concentration is adjusted.

### 7. Seventh Embodiment

The semiconductor device 100 of the first embodiment described above uses the first semiconductor region 110 formed in the semiconductor substrate 101. On the other hand, a semiconductor device 100 of a seventh embodiment of the present disclosure differs from the first embodiment described above in using a first semiconductor region protruding from a surface of the semiconductor substrate 101.

[Configuration of a Semiconductor Device]

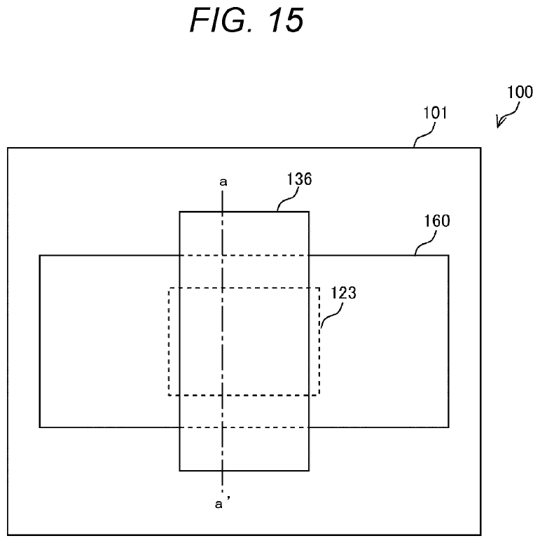

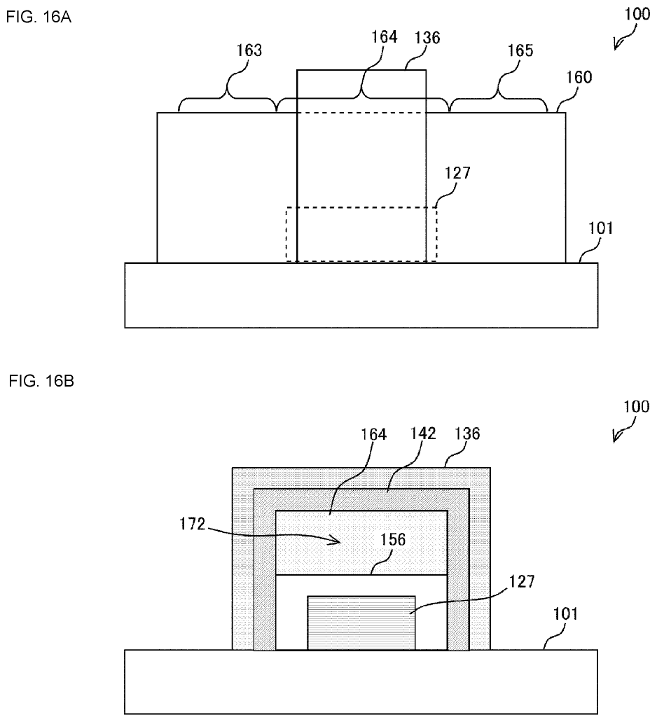

FIG. 15 is a plan view showing an example configuration of a semiconductor device according to the seventh embodiment of the present disclosure. The semiconductor device 100 in this drawing differs from the semiconductor device 100 described above with reference to FIG. 1 in that a first semiconductor region 160 is formed so as to protrude from a surface of the semiconductor substrate 101, and a gate electrode 136 is provided in place of the gate electrode 132.

[Configurations of a Side Surface and a Cross-Section of a Semiconductor Device]

FIG. 16 is diagrams showing an example configuration of a semiconductor device according to the seventh embodiment of the present disclosure. A of the drawing shows the configuration of a side surface of a semiconductor device 100, and B of the drawing shows the configuration of a cross-section of the semiconductor device 100.

In A of the drawing, a source region 163, a channel formation region 164, and a drain region 165 are disposed adjacent to one another in the first semiconductor region 160 formed so as to protrude from the semiconductor substrate 101. Further, the gate electrode 136 is formed in a shape to surround the channel formation region 164. Furthermore, a second semiconductor region 127 is disposed in the first semiconductor region 160.

B of the drawing is a cross-sectional view of the semiconductor device 100, taken along the a-a′ line defined in FIG. 15. As shown in the drawing, the gate electrode 136 is disposed adjacent to the channel formation region 164 of the first semiconductor region 160 via an insulating film 142. Further, the second semiconductor region 127 is disposed on a bottom portion of the first semiconductor region 160. A depletion layer 156 is formed between this second semiconductor region 127 and the first semiconductor region 160. A channel 172 in the drawing is formed in the channel formation region 164, and the direction in which majority carriers flow is perpendicular to the paper surface.

The other components of the semiconductor device 100 are similar to the components of the semiconductor device 100 described in the first embodiment of the present disclosure, and therefore, explanation of them is not made herein.

As described above, the semiconductor device 100 of the seventh embodiment of the present disclosure can reduce the influence of the trap at the interface on the back surface of the semiconductor substrate 101 in the first semiconductor region 160 having a shape protruding from the semiconductor substrate 101.

<8. Example Application to an Imaging Device>

The technology (the present technology) according to the present disclosure can be applied to various products. For example, the present technology may be used in an imaging device mounted in an imaging apparatus such as a camera.

[Configuration of an Imaging Device]

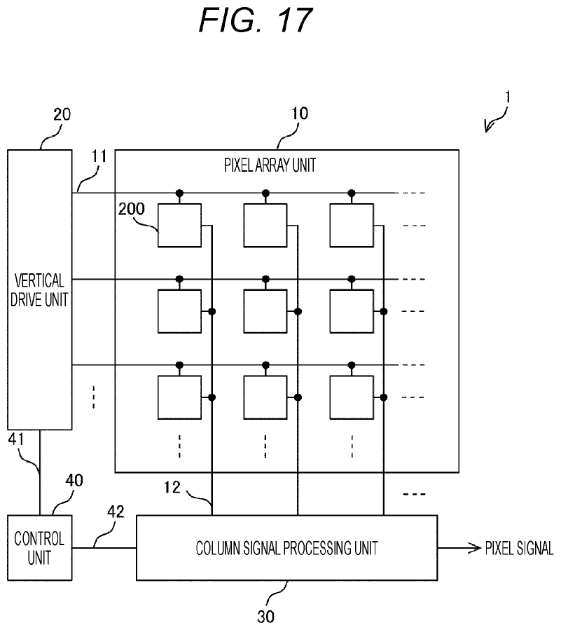

FIG. 17 is a diagram showing an example configuration of an imaging device to which the present technology can be applied. An imaging device 1 in this drawing includes a pixel array unit 10, a vertical drive unit 20, a column signal processing unit 30, and a control unit 40.

The pixel array unit 10 is formed with pixels 200 arranged in a two-dimensional grid pattern. Here, a pixel 200 generates an image signal in accordance with emitted light. This pixel 200 includes a photoelectric conversion unit that generates an electric charge in accordance with the emitted light. The pixel 200 further includes a pixel circuit. This pixel circuit generates an image signal based on the electric charge generated by the photoelectric conversion unit. The generation of the image signal is controlled by a control signal generated by the vertical drive unit 20 described later. In the pixel array unit 10, signal lines 11 and 12 are arranged in an X-Y matrix. The signal lines 11 are signal lines that transmit control signals for the pixel circuits in the pixels 200, are provided for the respective rows in the pixel array unit 10, and are designed to be shared by the pixels 200 aligned in each row. The signal lines 12 are signal lines that transmit image signals generated by the pixel circuits of the pixels 200, are provided for the respective columns in the pixel array unit 10, and are designed to be shared by the pixels 200 aligned in each column. These photoelectric conversion units and pixel circuits are formed in a semiconductor substrate.

The vertical drive unit 20 generates control signals for the pixel circuits of the pixels 200. This vertical drive unit 20 transmits the generated control signals to the pixels 200 via the signal lines 11 in the drawing. The column signal processing unit 30 processes image signals generated by the pixels 200. This column signal processing unit 30 processes the image signals transmitted from the pixels 200 via the signal lines 12 in the drawing. The processing at the column signal processing unit 30 corresponds to analog-to-digital conversion for converting analog image signals generated in the pixels 200 into digital image signals, for example. The image signals processed by the column signal processing unit 30 are output as image signals of the imaging device 1. The control unit 40 controls the entire imaging device 1. This control unit 40 generates and outputs control signals for controlling the vertical drive unit 20 and the column signal processing unit 30, to control the imaging device 1. The control signals generated by the control unit 40 are transmitted to the vertical drive unit 20 and the column signal processing unit 30 through signal lines 41 and 42, respectively.

<Example Configuration of a Pixel>

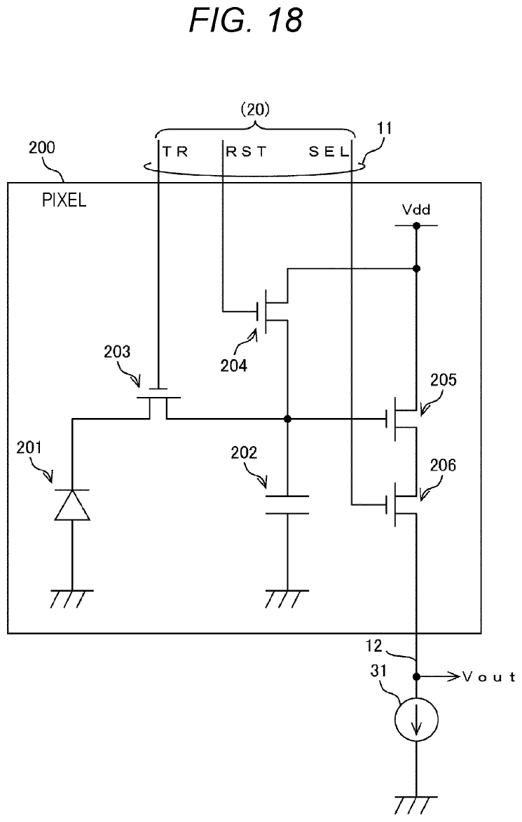

FIG. 18 is a diagram showing an example configuration of a pixel to which the present technology can be applied. This drawing is a circuit diagram showing an example configuration of a pixel 200. The pixel 200 in this drawing includes a photoelectric conversion unit 201, a charge retention unit 202, and MOS transistors 203 to 206.

The anode of the photoelectric conversion unit 201 is grounded, and the cathode is connected to the source of the MOS transistor 203. The drain of the MOS transistor 203 is connected to the source of the MOS transistor 204, the gate of the MOS transistor 205 is connected to one end of the charge retention unit 202. The other end of the charge retention unit 202 is grounded. The drains of the MOS transistors 204 and 205 are both connected to a power supply line Vdd, and the source of the MOS transistors 205 is connected to the drain of the MOS transistor 206. The source of the MOS transistor 206 is connected to a signal line 12. The gates of the MOS transistors 203, 204, and 206 are connected to a transfer signal line TR, a reset signal line RST, and a selection signal line SEL, respectively. Note that the transfer signal line TR, the reset signal line RST, and the selection signal line SEL constitute a signal line 11. Note that the signal line 12 is connected to a constant current source 31 disposed in the column signal processing unit 30.

The photoelectric conversion unit 201 generates an electric charge corresponding to emitted light as described above. A photodiode can be used as the photoelectric conversion unit 201. Further, the charge retention unit 202 and the MOS transistors 203 to 206 constitute a pixel circuit.

The MOS transistor 203 is a transistor that transfers the electric charge generated by photoelectric conversion performed by the photoelectric conversion unit 201 to the charge retention unit 202. The charge transfer at the MOS transistor 203 is controlled by a signal transmitted through the transfer signal line TR. The charge retention unit 202 is a capacitor that holds the electric charge transferred by the MOS transistor 203. The MOS transistor 205 is a transistor that generates a signal based on the electric charge held by the charge retention unit 202. The MOS transistor 206 is a transistor that outputs the signal generated by the MOS transistor 205 as an image signal to the signal line 12. This MOS transistor 206 is controlled by a signal transmitted through the selection signal line SEL.

The MOS transistor 204 is a transistor that resets the charge retention unit 202 by discharging the electric charge held by the charge retention unit 202 to the power supply line Vdd. The resetting by this MOS transistor 204 is controlled by a signal transmitted through the reset signal line RST, and is performed before the charge transfer to be performed by the MOS transistor 203. Note that, at the time of this resetting, the photoelectric conversion unit 201 can also be reset by making the MOS transistor 203 conductive. In this manner, the pixel circuit converts the electric charge generated by the photoelectric conversion unit 201 into an image signal.

The source of the MOS transistor 206 is connected to the constant current source 31 via the signal line 12. This constant current source 31 forms a constant current load of the MOS transistor 205. That is, the MOS transistor 205 forms a source follower circuit via the MOS transistor 206. The semiconductor devices 100 described above with reference to FIGS. 1 and 2 and FIG. 6 can be used as MOS transistors of the pixel 200. Further, the semiconductor device 100 described above with reference to FIG. 7 is preferably used as the MOS transistor 205. This is because the influence of fluctuations in the voltage of the constant current load connected to the source can be reduced.

[Configuration of a Cross-Section of an Imaging Device]

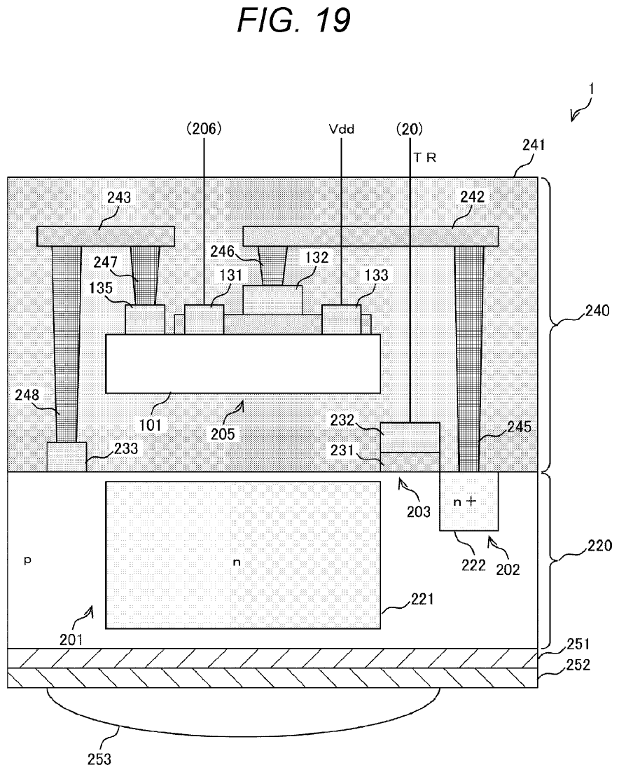

FIG. 19 is a cross-sectional view showing an example configuration of an imaging device to which the present technology can be applied. This drawing is a cross-sectional view showing an example configuration of an imaging device 1. The imaging device 1 in this drawing represents an example in which two semiconductor substrates are stacked. Specifically, the imaging device 1 in this drawing is formed stacking a semiconductor substrate 220 and a semiconductor substrate 101 forming a semiconductor device 100. A photoelectric conversion unit 201, a MOS transistor 203, and a charge retention unit 202 are disposed in the semiconductor substrate 220. MOS transistors 204 to 206 are disposed in the semiconductor substrate 101. In this drawing, the MOS transistor 205 is shown as an example. The semiconductor device 100 described above with reference to FIG. 6 can be used as the MOS transistor 205.

In the semiconductor substrate 220, n-type semiconductor regions 221 and 222 are disposed. For convenience, the semiconductor substrate 220 is formed in a p-type well region. The photoelectric conversion unit 201 is formed with the n-type semiconductor region 221 and the p-type semiconductor substrate 220 around the n-type semiconductor region 221. A photodiode is formed by the p-n junction at the interface between the n-type semiconductor region 221 and the p-type semiconductor substrate 220, and photoelectric conversion is performed. The n-type semiconductor region 222 forms a floating diffusion, and holds the electric charge generated by the photoelectric conversion unit 201. The MOS transistor 203 is a MOS transistor that has the n-type semiconductor regions 221 and 222 as the source and the drain, and uses a well region between the n-type semiconductor regions 221 and 222 as the channel formation region. A gate electrode 232 of the MOS transistor 203 is formed on the semiconductor substrate 220 via an insulating film 231.

A wiring region 240 is formed on a surface of the semiconductor substrate 220. In the wiring region 240, the wiring lines constituting the circuit of the pixel 200, and an insulating layer 241 that insulates the wiring lines are disposed. Further, the MOS transistor 205 and the like are disposed in the wiring region 240. The MOS transistor 205 and the like, and a charge retention unit 222 and the like disposed in the semiconductor substrate 220 are connected by wiring lines 242 and 243, and via plugs 245 to 248. Further, an electrode 233 is disposed on the semiconductor substrate 220. This electrode 233 forms a well contact. Note that the semiconductor substrate 220 is an example of the second semiconductor substrate disclosed in the claims.

The n-type semiconductor region 222 forming the charge retention unit 222 and the gate electrode 132 of the MOS transistor 205 are connected by the via plug 245, the wiring line 242, and the via plug 246. Note that the wiring lines of the gate of the MOS transistor 203 and the source and drain of the MOS transistor 205 are not shown in the drawing. Note that the well contact of the semiconductor substrate 220 and the well contact of the semiconductor substrate 101 forming the MOS transistor 205 are connected to each other. Specifically, the electrode 233 and the electrode 135 are connected by the wiring line 243 and the via plugs 247 and 248.

A protective film 251, a color filter 252, and an on-chip lens 253 are formed in this order on the back surface of the semiconductor substrate 220.

A device obtained by grinding and thinning a semiconductor substrate is used as a device stacked on another semiconductor substrate 220, like the MOS transistor 205 disposed in the imaging device 1 shown in the drawing. This is to reduce the height of the imaging device 1. As a semiconductor device 100 of the present disclosure is used as such a MOS transistor 205, the influence of a trap at the interface on the back surface of the semiconductor substrate 101 can be reduced, and noise of the imaging device 1 can also be reduced.

Lastly, the explanation of each embodiment described above is an example of the present disclosure, and the present disclosure is not limited to the embodiments described above. Accordingly, other than the respective embodiments described above, various changes may of course be made depending on the design and the like, without departing from the technical idea according to the present disclosure.

Also, the drawings relating to the embodiments described above are schematic, and the dimensional ratios and the like of the respective components do not always match the actual ones. Further, it is needless to say that the dimensional relationships and ratios may differ between the drawings.

Note that the present technology may also be embodied in the configurations described below.

(1) A semiconductor device including:

a first semiconductor region in which a source region, a channel formation region, and a drain region that are of the same conductivity type are provided;

a gate electrode disposed adjacent to the channel formation region via an insulating film disposed on a surface of the first semiconductor region; and

a second semiconductor region that is disposed adjacent to the channel formation region on a different surface from the surface on which the gate electrode is disposed, and forms a depletion layer in the channel formation region.

(2) The semiconductor device according to (1), in which the second semiconductor region is of a different conductivity type from a conductivity type of the first semiconductor region.

(3) The semiconductor device according to (2), further including an electrode disposed adjacent to the second semiconductor region.

(4) The semiconductor device according to (3), in which

the first semiconductor region is formed on a front surface of the semiconductor substrate,

the second semiconductor region is formed on a back surface of the semiconductor substrate, and

the electrode is disposed adjacent to the back surface of the semiconductor substrate.

(5) The semiconductor device according to (1), in which the second semiconductor region is disposed further adjacent to the source region and the drain region.

(6) The semiconductor device according to (1), in which

the source region, the channel formation region, and the drain region are formed in a region protruding from the semiconductor substrate, and

the gate electrode is formed in a shape that surrounds a surface of the channel formation region that protrudes.

(7) The semiconductor device according to (1), in which the second semiconductor region has different thicknesses in a vicinity of the source region and in a vicinity of the drain region.

(8) The semiconductor device according to (1), in which

the first semiconductor region is formed on a front surface of the semiconductor substrate, and

the second semiconductor region is formed with a pinning layer that pins a trap level on a back surface of the semiconductor substrate.

(9) The semiconductor device according to (8), in which the second semiconductor region has different impurity concentrations in a vicinity of the source region and in a vicinity of the drain region.

(10) A semiconductor device including:

a first semiconductor substrate in which a semiconductor device is disposed, the semiconductor device in the first semiconductor substrate including: a first semiconductor region in which a source region, a channel formation region, and a drain region that are of the same conductivity type are provided; a gate electrode disposed adjacent to the channel formation region via an insulating film disposed on a surface of the first semiconductor region; and a second semiconductor region that is disposed adjacent to the channel formation region on a different surface from the surface on which the gate electrode is disposed, and forms a depletion layer in the channel formation region; and a second semiconductor substrate on which the first semiconductor substrate is stacked.

(11) A method for manufacturing a semiconductor device,

the method including:

a step of forming a first semiconductor region in which a source region, a channel formation region, and a drain region that are of the same conductivity type are provided;

a step of forming a gate electrode disposed adjacent to the channel formation region via an insulating film formed on a surface of the first semiconductor region; and

a step of forming a second semiconductor region that is disposed adjacent to the channel formation region on a different surface from the surface on which the gate electrode is disposed, and forms a depletion layer in the channel formation region.

### REFERENCE SIGNS LIST

1 Imaging device
30 Column signal processing unit
31 Constant current source
100 Semiconductor device
101, 220 Semiconductor substrate
110, 116 to 118, 160 First semiconductor region
113, 163 Source region
114, 164 Channel formation region
115, 165 Drain region
120 to 127 Second semiconductor region
131 Source electrode
132, 136 Gate electrode
133 Drain electrode
134 Back-surface electrode
140 to 142 Insulating film
151 to 157 Depletion layer
171, 172 Channel
200 Pixel
203 to 206 MOS transistor

1. A semiconductor device comprising:
a first semiconductor region in which a source region, a channel formation region, and a drain region that are of the same conductivity type are provided;
a gate electrode disposed adjacent to the channel formation region via an insulating film disposed on a surface of the first semiconductor region; and
a second semiconductor region that is disposed adjacent to the channel formation region on a different surface from a surface on which the gate electrode is disposed, and forms a depletion layer in the channel formation region.

2. The semiconductor device according to claim 1, wherein the second semiconductor region is of a different conductivity type from a conductivity type of the first semiconductor region.

3. The semiconductor device according to claim 2, further comprising an electrode disposed adjacent to the second semiconductor region.

4. The semiconductor device according to claim 3, wherein
the first semiconductor region is formed on a front surface of the semiconductor substrate,
the second semiconductor region is formed on a back surface of the semiconductor substrate, and
the electrode is disposed adjacent to the back surface of the semiconductor substrate.

5. The semiconductor device according to claim 1, wherein the second semiconductor region is disposed further adjacent to the source region and the drain region.

6. The semiconductor device according to claim 1, wherein
the source region, the channel formation region, and the drain region are formed in a region protruding from the semiconductor substrate, and
the gate electrode is formed in a shape that surrounds a surface of the channel formation region that protrudes.

7. The semiconductor device according to claim 1, wherein the second semiconductor region has different thicknesses in a vicinity of the source region and in a vicinity of the drain region.

8. The semiconductor device according to claim 1, wherein
the first semiconductor region is formed on a front surface of the semiconductor substrate, and
the second semiconductor region is formed with a pinning layer that pins a trap level on a back surface of the semiconductor substrate.

9. The semiconductor device according to claim 8, wherein the second semiconductor region has different impurity concentrations in a vicinity of the source region and in a vicinity of the drain region.

10. A semiconductor device comprising:
a first semiconductor substrate in which a semiconductor device is disposed, the semiconductor device in the first semiconductor substrate including: a first semiconductor region in which a source region, a channel formation region, and a drain region that are of the same conductivity type are provided; a gate electrode disposed adjacent to the channel formation region via an insulating film disposed on a surface of the first semiconductor region; and a second semiconductor region that is disposed adjacent to the channel formation region on a different surface from a surface on which the gate electrode is disposed, and forms a depletion layer in the channel formation region; and
a second semiconductor substrate on which the first semiconductor substrate is stacked.

11. A method for manufacturing a semiconductor device,
the method comprising:
a step of forming a first semiconductor region in which a source region, a channel formation region, and a drain region that are of the same conductivity type are provided;
a step of forming a gate electrode disposed adjacent to the channel formation region via an insulating film formed on a surface of the first semiconductor region; and
a step of forming a second semiconductor region that is disposed adjacent to the channel formation region on a different surface from a surface on which the gate electrode is disposed, and forms a depletion layer in the channel formation region.
